(19) United States
(12) Patent Application Publication
(10) Pub. No.: US 2026/0169323 A1
(43) Pub. Date: Jun. 18, 2026

(54) DISPLAY SUBSTRATE, MANUFACTURING METHOD THEREFOR AND DISPLAY DEVICE

(71) Applicant: BOE Technology Group Co., Ltd., Beijing (CN)

(72) Inventors: Chunyang WANG, Beijing (CN); Bingwei WANG, Beijing (CN); Hejin WANG, Beijing (CN); Hao ZHANG, Beijing (CN); Zheng LIU, Beijing (CN)

(21) Appl. No.: 18/711,186

(22) PCT Filed: Mar. 3, 2023
(86) PCT No.: PCT/CN2023/079569

§ 371 Date: May 17, 2024

(51) Int. Cl. G02F 1/1333

(52) U.S. Cl. CPC G02F 1/133305

(57) ABSTRACT

The disclosure provides a display substrate, a manufacturing method therefor and a display device. The display substrate includes: a flexible substrate, and a first planarization layer, a first passivation layer, a second planarization layer and a second passivation layer that are sequentially arranged on the flexible substrate. The flexible substrate includes a plurality of island regions arranged in an array and bridge regions configured to connect the island regions. Each island region includes a display region and a non-display region surrounding the display region. The second passivation layer is provided with a concave structure at a side, close to a corresponding bridge region, of the non-display region.

### CROSS-REFERENCE TO RELATED APPLICATIONS

This application is a National Stage of International Application No. PCT/CN 2023/079569, filed on Mar. 3, 2023, which is hereby incorporated by reference in its entirety.

### TECHNICAL FIELD

The disclosure relates to the technical field of display, in particular to a display substrate, a manufacturing method therefor and a display device.

### BACKGROUND

A display device (for example, a stretchable one) generally adopts an island (a region with pixel units) and a bridge (a region with signal wires) for connection. Desirable stretchability is achievable by stretching a hollowed region between the pixel units and the signal wires. A connection position between the island and the bridge is generally slotted for preventing water vapor invasion through a bridge region during in-island encapsulation. But some organic adhesive will remain in a slot inevitably during actual manufacturing, resulting in an encapsulation failure. In view of that, it is a pressing technical problem to avoid a risk of adhesive residue during exposure in deep holes on the premise of guaranteeing an encapsulation effect at the connection position of the island and the bridge.

### SUMMARY

The disclosure provides a display substrate, a manufacturing method therefor and a display device. Specific solutions are as follows.

An embodiment of the disclosure provides a display substrate. The display substrate includes: a flexible substrate; and a first planarization layer, a first passivation layer, a second planarization layer and a second passivation layer that are sequentially arranged on the flexible substrate; where the flexible substrate includes a plurality of island regions arranged in an array and bridge regions configured to connect the island regions. Each island region includes a display region and a non-display region surrounding the display region; the second passivation layer is provided with a concave structure at a side, close to a corresponding bridge region, of the non-display region; and a first planarization portion and a second planarization portion that are separated by the first passivation layer are arranged between the concave structure and the flexible substrate, and an orthographic projection of the first planarization portion on the flexible substrate and an orthographic projection of the second planarization portion on the flexible substrate at least partially do not overlap each other.

Optionally, in the embodiment of the disclosure, the first planarization portion and the first planarization layer are located on the same layer and made of the same material, and the second planarization portion and the second planarization layer are located on the same layer and made of the same material; and
the first planarization portion is provided with at least one first recess and the second planarization portion is provided with at least one second recess between the concave structure and the flexible substrate, and an orthographic projection of the at least one second recess on the flexible substrate and an orthographic projection of the at least one first recess on the flexible substrate do not overlap each other.

Optionally, in the embodiment of the disclosure, between the concave structure and the flexible substrate, a partial surface of a side, facing away from the flexible substrate, of the first passivation layer is flush with a surface of a side, facing away from the flexible substrate, of the second planarization portion; and the second passivation layer is in direct contact with the first passivation layer at a position corresponding to the first planarization portion.

Optionally, in the embodiment of the disclosure, the at least one first recess includes a first sub-recess and a second sub-recess that are separated by the first planarization portion, the first sub-recess is close to the display region, and the second sub-recess is close to the bridge region.

Optionally, in the embodiment of the disclosure, one second recess is provided; and the second planarization portion includes a first sub-portion located at a side, close to the display region, of the second recess and a second sub-portion located at a side, close to the bridge region, of the second recess.

Optionally, in the embodiment of the disclosure, the first sub-portion is separated from the second planarization layer located in the display region, and the second sub-portion is separated from the second planarization layer located in the bridge region.

Optionally, in the embodiment of the disclosure, the first sub-portion is connected with the second planarization layer located in the display region, and the second sub-portion is connected with the second planarization layer located in the bridge region.

Optionally, in the embodiment of the disclosure, one first recess is provided, one second recess is provided, and the second recess is at a side close to the bridge region.

Optionally, in the embodiment of the disclosure, the first planarization portion extends from the non-display region to the bridge region and is connected with the first planarization layer located in the bridge region.

Optionally, in the embodiment of the disclosure, the second planarization portion is separated from the second planarization layer located in both the display region and the bridge region.

Optionally, in the embodiment of the disclosure, the second planarization portion is connected with the second planarization layer located in the display region and separated from the second planarization layer located in the bridge region.

Optionally, in the embodiment of the disclosure, one first recess is provided, one second recess is provided, and the second recess is at a side close to the display region.

Optionally, in the embodiment of the disclosure, the first planarization portion extends from the non-display region to the display region and is connected with the first planarization layer located in the display region.

Optionally, in the embodiment of the disclosure, the second planarization portion is separated from the second planarization layer located in both the display region and the bridge region.

Optionally, in the embodiment of the disclosure, the second planarization portion is connected with the second planarization layer located in the bridge region and separated from the second planarization layer located in the display region.

Optionally, in the embodiment of the disclosure, the bridge region is a bendable bridge or an I-shaped bridge.

Optionally, in the embodiment of the disclosure, the bridge region is the bendable bridge, and the bendable bridge includes a first signal wire and a second signal wire that are arranged side by side on the flexible substrate; at a non-corner position of the bendable bridge, the first signal wire is arranged closer to an inner side of a corner of the bendable bridge than the second signal wire; and at the corner of the bendable bridge, the first signal wire and a metal wire that is close to an outer side of the corner are lap-jointed.

Optionally, in the embodiment of the disclosure, at the corner of the bendable bridge, the first signal wire is in direct contact with the flexible substrate.

Optionally, in the embodiment of the disclosure, at the corner of the bendable bridge, at least one hole penetrating in a thickness direction of the flexible substrate is provided at a position on the flexible substrate excluding positions where the first signal wire and the second signal wire are arranged.

Optionally, in the embodiment of the disclosure, the display substrate further includes a first source-drain electrode layer arranged on the flexible substrate, where the first source-drain electrode layer is manufactured on the same layer as the first signal wire.

Optionally, in the embodiment of the disclosure, the display substrate further includes an anode layer at a side, facing away from the flexible substrate, of the first source-drain electrode layer, where the anode layer is manufactured on the same layer as the metal wire.

Optionally, in the embodiment of the disclosure, the display substrate further includes a second source-drain electrode layer between the first source-drain electrode layer and the flexible substrate, where the second source-drain electrode layer is manufactured on the same layer as the metal wire.

Optionally, in the embodiment of the disclosure, the display substrate further includes a thin film encapsulation layer, where the thin film encapsulation layer includes a first inorganic encapsulation layer, an organic encapsulation layer and a second inorganic encapsulation layer; the organic encapsulation layer is arranged at a side, close to the display region, of the concave structure; and in the non-display region and the bridge region, the first inorganic encapsulation layer and the second inorganic encapsulation layer are in direct contact with each other and cover the concave structure.

Correspondingly, the embodiment of the disclosure provides a display device. The display device includes: the display substrate according to any one described above.

Correspondingly, the embodiment of the disclosure provides a manufacturing method for a display substrate. The manufacturing method is configured to manufacture the display substrate according to any one described above, and the manufacturing method includes:
providing a flexible substrate, where the flexible substrate includes a plurality of island regions arranged in an array and bridge regions configured to connect the island regions, and each island region includes a display region and a non-display region surrounding the display region;
arranging a first planarization layer on the flexible substrate;
forming a pattern of the first planarization layer at a side, close to a corresponding bridge region, of the non-display region by adopting a patterning process;
forming a first passivation layer at a side, facing away from the flexible substrate, of the first planarization layer;
forming a second planarization layer at a side, facing away from the flexible substrate, of the first passivation layer;
forming a pattern of the second planarization layer at the side, close to the corresponding bridge region, of the non-display region by adopting the patterning process; and
forming a second passivation layer at the side, close to the corresponding bridge region, of the non-display region and on a surface of a side, facing away from the flexible substrate, of the second planarization layer. The second passivation layer is provided with a concave structure, a first planarization portion and a second planarization portion that are separated by the first passivation layer are arranged between the concave structure and the flexible substrate, and an orthographic projection of the first planarization portion on the flexible substrate and an orthographic projection of the second planarization portion on the flexible substrate at least partially do not overlap each other.

### Brief Description of Figures

FIG. 1 is a schematic structural diagram of a top view of a display substrate according to an embodiment of the disclosure.

FIG. 2 is a schematic structural diagram of a section in a direction indicated by MM in FIG. 1.

FIG. 3 is another schematic structural diagram of the section in the direction indicated by MM in FIG. 1.

FIG. 4 is another schematic structural diagram of the section in the direction indicated by MM in FIG. 1.

FIG. 5 is another schematic structural diagram of the section in the direction indicated by MM in FIG. 1.

FIG. 6 is another schematic structural diagram of the section in the direction indicated by MM in FIG. 1.

FIG. 7 is another schematic structural diagram of the section in the direction indicated by MM in FIG. 1.

FIG. 8 is a schematic structural diagram of a top view of a display substrate with a bridge region being a bendable bridge according to an embodiment of the disclosure.

FIG. 9 is a schematic structural diagram of a top view of a display substrate with a bridge region being an I-shaped bridge according to an embodiment of the disclosure.

FIG. 10 is a schematic structural diagram of a top view of the bendable bridge at a corner position in FIG. 8.

FIG. 11 is a schematic structural diagram of a section in a direction indicated by NN in FIG. 10.

FIG. 12 is another schematic structural diagram of the section in the direction indicated by NN in FIG. 10.

FIG. 13 is another schematic structural diagram of a top view of the bendable bridge at the corner position in FIG. 8.

FIG. 14 is another schematic structural diagram of the section in the direction indicated by NN in FIG. 10.

FIG. 15 is a flowchart of a manufacturing method for a display substrate according to an embodiment of the disclosure.

### DETAILED DESCRIPTION

In order to make objectives, technical solutions and advantages of embodiments of the disclosure clearer, the technical solutions of the embodiments of the disclosure will be clearly and completely described with reference to accompanying drawings of the embodiments of the disclosure. Apparently, the described embodiments are some embodiments rather than all embodiments of the disclosure. In addition, the embodiments in the disclosure and features in the embodiments can be combined mutually if there is no conflict. All the other embodiments derived by a person of ordinary skill in the art from the described embodiments of the disclosure without creative efforts should fall within the protection scope of the disclosure.

Unless otherwise defined, technical terms or scientific terms used in the disclosure should have ordinary meanings understandable by a person of ordinary skill in the art to which the disclosure belongs. As used in the disclosure, similar words such as “comprise” or “include” indicate that the element or object appearing before the word cover elements or objects listed after the word and their equivalents, but do not exclude other elements or objects.

It should be noted that a size and a shape of each figure in the accompanying drawings do not reflect true scales, and are merely intended to schematically describe contents of the disclosure. Identical or similar reference numerals denote identical or similar elements, or elements having identical or similar functions throughout.

In the related art, when a display panel (for example, a stretchable display panel) is designed, a connection position of the island and the bridge is slotted for preventing water vapor invasion through a bridge region during in-island encapsulation. When a pattern of a planarization layer close to an encapsulation layer is made, a thickness of the planarization layer at a corresponding slot is greater than a thickness of that in the other areas, especially in the case that the planarization layer is used for manufacturing a post spacer located in an island region. In this case, formation of the post spacer is affected if a large exposure dose is used, and an adhesive corresponding to the planarization layer remains in a corresponding slot if a normal exposure dose is used, resulting in an encapsulation failure. An existing solution is to expose secondarily the remaining adhesive of the planarization layer in the slot by adding a mask.

However, complexity of the process is undoubtedly increased. In addition, a deeper slot may cause an increase of a risk of residue for exposure of an organic layer such as a rear post spacer (PS).

In view of this, the embodiments of the disclosure provide a display substrate, a manufacturing method therefor and a display device for avoiding risk of adhesive residue during exposure in deep holes while an encapsulation effect is guaranteed at a connection position of the island and the bridge.

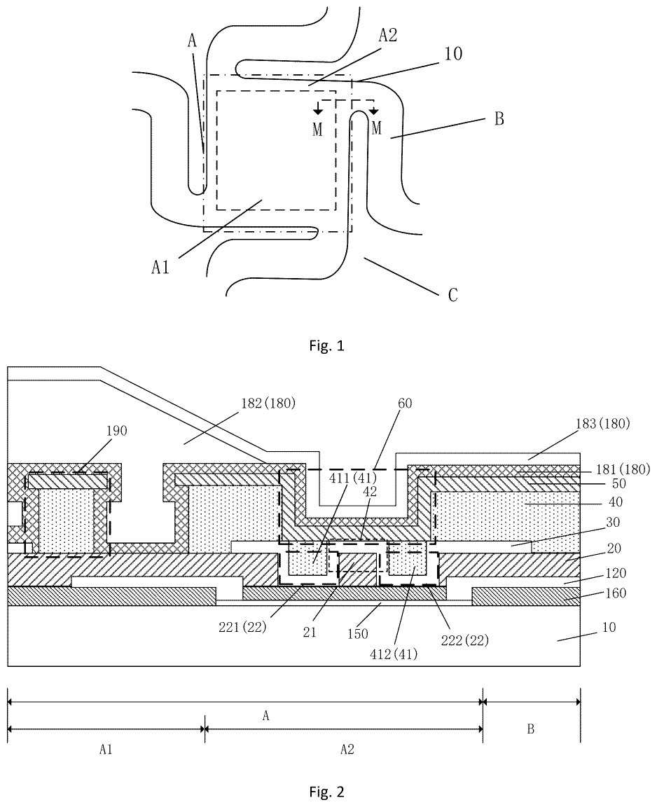

With reference to FIGS. 1 and 2, FIG. 1 is a schematic structural diagram of a top view of a part of a display substrate (for example, a stretchable display substrate) according to an embodiment of the disclosure, and FIG. 2 is a schematic structural diagram of a section in a direction indicated by MM in FIG. 1. Specifically, the display substrate includes: a flexible substrate 10; and a first planarization layer 20, a first passivation layer 30, a second planarization layer 40 and a second passivation layer 50 that are sequentially arranged on the flexible substrate 10. The flexible substrate 10 includes a plurality of island regions A arranged in an array and bridge regions B configured to connect the island regions A.

During specific implementation, the flexible substrate 10 may has a structure including two flexible base layers or a structure including three flexible base layers, which is not limited herein. A buffer layer may be arranged between two adjacent flexible base layers. For example, under the condition that the flexible substrate 10 includes two flexible base layers, the buffer layer is arranged between the two flexible base layers. For example, under the condition that the flexible substrate 10 includes three flexible base layers, a buffer layer is arranged between every two adjacent flexible base layers; and the flexible substrate 10 is provided with two buffer layers in total accordingly.

In addition, the flexible substrate 10 includes the plurality of island regions A arranged in an array, and the bridge region B configured to connect the island regions A. In addition, a hollowed region C is arranged between the island region A and the bridge region B. The number of the island regions A, the number of the bridge regions B and the number of the hollowed regions C can be set according to actual application demand, and are not limited herein. In addition, a plurality of sub-pixels are arranged in each island region A, and the display substrate achieves certain stretchability by stretching the hollowed region C.

Each island region A includes a display region A1 and a non-display region A2 surrounding the display region A1. The second passivation layer 50 is provided with a concave structure 60 at a side, close to a corresponding bridge region B, of the non-display region A2. A first planarization portion 21 and a second planarization portion 41 that are separated by the first passivation layer 30 are arranged between the concave structure 60 and the flexible substrate 10, and an orthographic projection of the first planarization portion 21 on the flexible substrate 10 and an orthographic projection of the second planarization portion 41 on the flexible substrate 10 at least partially do not overlap each other.

During specific implementation, each island region A includes the display region A1 and the non-display region A2 surrounding the display region A1, as shown in FIG. 1 which is a schematic diagram of distribution of the regions on the flexible substrate 10. Of course, the flexible substrate 10 may be divided according to the actual application demand, which is not limited herein.

In addition, the display substrate further includes the first planarization layer 20, the first passivation layer 30, the second planarization layer 40 and the second passivation layer 50 that are sequentially arranged on the flexible substrate 10. The second passivation layer 50 is provided with the concave structure 60 at the side, close to the corresponding bridge region B, of the non-display region A2. A surface of a side, close to the flexible substrate 10, of the concave structure 60 is conformally arranged on surfaces, far away from the flexible substrate 10, of the first passivation layer 30 and the second planarization portion 41. Thus, flatness of a subsequent film layer is guaranteed. In addition, the first planarization portion 21 and a second planarization portion 41 that are separated by the first passivation layer 30 are arranged between the concave structure 60 and the flexible substrate 10, and the orthographic projection of the first planarization portion 21 on the flexible substrate 10 and the orthographic projection of the second planarization portion 41 on the flexible substrate 10 at least partially do not overlap each other. In an illustrative embodiment, the orthographic projection of the first planarization portion 21 on the flexible substrate 10 and the orthographic projection of the second planarization portion 41 on the flexible substrate 10 completely do not overlap each other. In an illustrative embodiment, the orthographic projection of the first planarization portion 21 on the flexible substrate 10 and the orthographic projection of the second planarization portion 41 on the flexible substrate 10 partially do not overlap each other and partially overlap each other. Specific arrangements of the first planarization portion 21 and the second planarization portion 41 can be set according to actual application demand, and are not limited herein.

That is, a pattern of the first planarization layer 20 and a pattern of the second planarization layer 40 are reserved between the concave structure 60 and the flexible substrate 10. In this way, the first planarization portion 21 and the second planarization portion 41 located between the concave structure 60 and the flexible substrate 10 raise the concave structure 60, thus avoiding the risk of adhesive residue during exposure in deep holes in a subsequent process. In the embodiment of the disclosure, between the concave structure 60 and the flexible substrate 10, the first planarization portion 21 is provided with at least one first recess 22 and the second planarization portion 41 is provided with at least one second recess 42, and orthographic projections of the second recesses 42 on the flexible substrate 10 and orthographic projections of the first recesses 22 on the flexible substrate 10 do not overlap each other.

In some embodiments, the first planarization portion 21 and the first planarization layer 20 are located on the same layer and made of the same material, that is, the first planarization portion 21 may be a part of the first planarization layer 20. The second planarization portion 41 and the second planarization layer 40 are located on the same layer and made of the same material, that is, the second planarization portion 41 may be a part of the second planarization layer 40. In this way, the manufacturing efficiency of the display substrate is improved.

It should be noted that in an illustrative embodiment as shown in FIG. 2, a thickness of the first planarization portion 21 is not greater than a thickness of a portion of the first planarization layer 20 excluding the first planarization portion 21. A thickness of the second planarization portion 41 is less than or equal to the thickness of the first planarization portion 21. In an illustrative embodiment, the thickness of the second planarization portion 41 may be equal to a thickness of a portion of the second planarization layer 40 excluding the second planarization portion 41. In an illustrative embodiment, the thickness of the second planarization portion 41 may be smaller than the thickness of the portion of the second planarization layer 40 excluding the second planarization portion 41. In an illustrative embodiment, the thickness of the second planarization portion 41 may be greater than the thickness of the portion of the second planarization layer 40 excluding the second planarization portion 41. Of course, specific thicknesses of the first planarization portion 21 and the second planarization portion 41 can be set according to actual application demands, and are not limited herein.

In an illustrative embodiment, at a position corresponding to the second planarization portion 41, a partial pattern of the first planarization layer is further arranged between the first passivation layer 30 and an interlayer insulation layer 160, and a thickness of this partial pattern is smaller than the thickness of the first planarization portion 21.

During specific implementation, between the concave structure 60 and the flexible substrate 10, the first planarization portion 21 is provided with at least one first recess 22, and the first recesses 22 completely penetrate in a thickness direction of the first planarization layer 20. The number of the at least one first recess 22 may be one or more, which is not limited herein. In addition, the second planarization portion 41 is provided with at least one second recess 42, and the second recesses 42 completely penetrate in a thickness direction of the second planarization layer 40. The number of the at least one second recess 42 may be one or more, which is not limited herein. In the illustrative embodiment as shown in FIG. 2, two first recesses 22 are provided, and one second recess 42 is provided. In addition, the orthographic projection of each second recess 42 on the flexible substrate 10 and the orthographic projection of each first recess 22 on the flexible substrate 10 do not overlap each other. That is, the second recesses 42 and the first recesses 22 are staggered. In this way, the layout space of the display substrate is reduced.

In the embodiment of the disclosure, between the concave structure 60 and the flexible substrate 10, a partial surface of a side, facing away from the flexible substrate 10, of the first passivation layer 30 is flush with a surface of a side, facing away from the flexible substrate 10, of the second planarization portion 41. In this way, a flush arrangement of a surface of a side, close to the flexible substrate 10, of the concave structure 60 is ensured, stability of film layers after the first passivation layer 30 is ensured during actual manufacturing, and usability of the display substrate is improved.

In some embodiments, between the concave structure 60 and the flexible substrate 10, the second passivation layer 50 is in direct contact with the first passivation layer 30 at a position corresponding to the first planarization portion 21. With such design, the two inorganic layers are in close contact, thus advantageously preventing water vapor from entering the display region A1.

In some embodiments, between the concave structure 60 and the flexible substrate 10, the second passivation layer 50 is in direct contact with the first passivation layer 30 at a position corresponding to the first planarization portion 21 and/or the second planarization portion 41. With such design, the two inorganic layers are in close contact, thus advantageously preventing water vapor from entering the display region A1.

In some embodiments, the display substrate further includes a thin film encapsulation layer 180. The thin film encapsulation layer 180 includes a first inorganic encapsulation layer 181, an organic encapsulation layer 182 and a second inorganic encapsulation layer 183. The organic encapsulation layer 182 is arranged at a side, close to the display region A1, of the concave structure 60 (that is, the organic encapsulation layer 182 stops at the side, close to the display region A1, of the concave structure 60). In the non-display region A2 and the bridge region B, the first inorganic encapsulation layer 181 and the second inorganic encapsulation layer 183 are in direct contact with each other and cover the concave structure 60, that is, a portion of the first inorganic encapsulation layer 181 and a portion of the second inorganic encapsulation layer 183 that are in direct contact may extend from the non-display region A2 to the bridge region B. With such design, the first inorganic encapsulation layer 181 and the second inorganic encapsulation layer 183 are in direct contact, such that the water vapor is prevented from entering the display region A1. In addition, there is no organic encapsulation layer 182 at the position corresponding to the concave structure 60, such that stretchability of the display substrate is improved.

In some embodiments, the second passivation layer 50 and the first passivation layer 30 corresponding to the concave structure 60 may be separated from the second passivation layer 50 and the first passivation layer 30 of the display region A1 respectively. For example, in the display region A1, the second passivation layer 50 and the second planarization layer 40 form a plurality of mutually independent separation posts 190. The separation posts 190 separate the first passivation layer 30, and the first inorganic encapsulation layer 181 covers the separation posts 190.

The display substrate of the embodiments disclosed above has the stretchable performance, and may be a stretchable display substrate accordingly. Subsequent embodiments will be described with the stretchable display substrate as an example, but are not limited thereto.

In the embodiments of the disclosure, in combination with FIGS. 2 to 7, arrangements of the first recess 22 and the second recess 42 may include, but are not limited to, the following situations.

In an illustrative embodiment, at least one first recess 22 includes a first sub-recess 221 and a second sub-recess 222 that are separated by the first planarization portion 21, the first sub-recess 221 is provided close to the display region A1, and the second sub-recess 222 is provided close to the bridge region B.

With reference to the illustrative embodiment as shown in FIG. 2, at least one first recess 22 includes two first sub-recesses (a first sub-recess 221 and a second sub-recess 222) that are separated by the first planarization portion 21. The first sub-recess 221 is provided close to the display region A1, and the second sub-recess 222 is provided close to the bridge region B.

During actual manufacturing, when the first planarization layer 20 is patterned, merely a partial pattern may be reserved at a position corresponding to a middle position of the concave structure 60. In this way, the first planarization portion 21 reserved may separate the first sub-recess 221 and the second sub-recess 222 that are separated.

With reference to the illustrative embodiment as shown in FIG. 2, one second recess 42 is provided, and the second planarization portion 41 includes a first sub-portion 411 located at a side, close to the display region A1, of the second recess 42 and a second sub-portion 412 located at a side, close to the bridge region B, of the second recess 42.

During specific implementation, one second recess 42 is provided; and an orthographic projection of the first sub-recess 221 on the flexible substrate 10, an orthographic projection of the second sub-recess 222 on the flexible substrate 10 and an orthographic projection of the second recess 42 on the flexible substrate 10 do not overlap each other. The second planarization portion 41 includes a first sub-portion 411 located at a side, close to the display region A1, of the second recess 42 and a second sub-portion 412 located at a side, close to the bridge region B, of the second recess 42. In the illustrative embodiment as shown in FIG. 2, the first sub-portion 411 can be accommodated in the first sub-recess 221 and the second sub-portion 412 can be accommodated in the second sub-recess 222, thus ensuring structural stability of the display substrate.

With reference to the illustrative embodiment as shown in FIG. 2, the first sub-portion 411 is separated from the second planarization layer 40 located in the display region A1, and the second sub-portion 412 is separated from the second planarization layer 40 located in the bridge region B.

During specific implementation, the first sub-portion 411 is separated from the second planarization layer 40 located in the display region A1, and the second sub-portion 412 is separated from the second planarization layer 40 located in the bridge region B. In this way, an encapsulation effect of the display substrate at a connection position of the island and the bridge is improved.

It should be noted that a distance between the second planarization portion 41 and the first planarization portion 21 in a direction from the island region A to the bridge region B is smaller than a distance between the second planarization portion 41 and the second planarization layer arranged at a side, close to the display region A1, of the concave structure 60, and smaller than a distance between the second planarization portion 41 and the second planarization layer arranged at a side, close to the bridge region B, of the concave structure 60. With such design, a poor process caused by a serious segment difference since a gap between the first planarization portion 21 and the second planarization portion 41 is too large is avoided. Of course, a specific value of related distances can be set according to actual application demands, and is not elaborated herein.

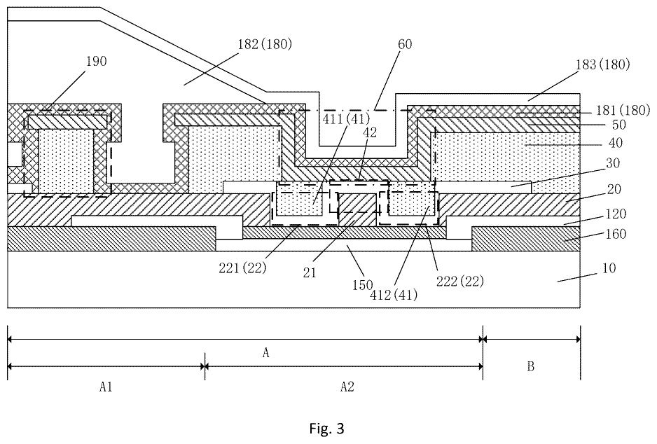

With reference to the illustrative embodiment as shown in FIG. 3, the first sub-portion 411 is connected with the second planarization layer 40 located in the display region A1, and the second sub-portion 412 is connected with the second planarization layer 40 located in the bridge region B.

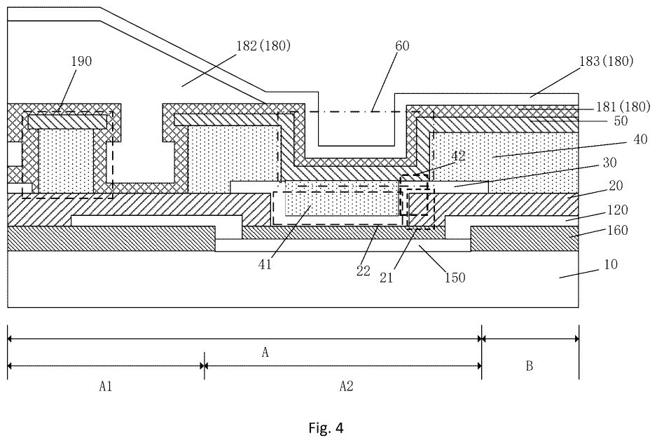

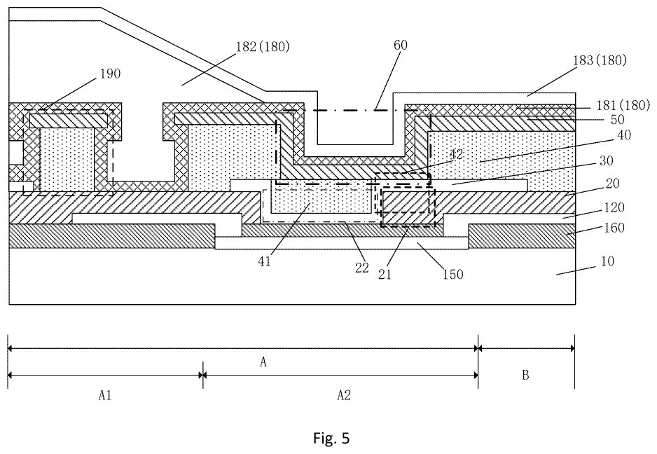

During specific implementation, the first sub-portion 411 is connected with the second planarization layer 40 located in the display region A1, and the second sub-portion 412 is connected with the second planarization layer 40 located in the bridge region B. During actual manufacturing, a radius of an opening of the concave structure 60 in the illustrative embodiment as shown in FIG. 3 is smaller than a radius of an opening of the concave structure 60 in the illustrative embodiment as shown in FIG. 2. Thus, the first sub-portion 411 is guaranteed to be connected with the second planarization layer 40 located in the display region A1. In this way, deflation of the second planarization layer 40 located in the display region A1 is facilitated during manufacturing, and film explosion of the second planarization layer 40 in the display region A1 is avoided. In addition, it is guaranteed that the second sub-portion 412 is connected with the second planarization layer 40 located in the bridge region B. In this way, deflation of the second planarization layer 40 located in the bridge region B is facilitated during manufacturing, and film explosion of the second planarization layer 40 in the bridge region B is avoided. The manufacturing efficiency of the display substrate is improved accordingly. In an illustrative embodiment, as shown in FIGS. 4 and 5, one first recess 22 is provided, one second recess 42 is provided, and the second recess 42 is provided at a side close to the bridge region B.

During specific implementation, as shown in FIGS. 4 and 5, one first recess 22 is provided, and one second recess 42 is provided. In addition, an area of the orthographic projection of the second recess 42 on the flexible substrate 10 is smaller than an area of the orthographic projection of the first recess 22 on the flexible substrate 10. In this way, a manufacturing process of the second planarization portion 41 between the concave structure 60 and the flexible substrate 10 is simpler, and the manufacturing efficiency of the display substrate is improved.

With reference to the illustrative embodiment as shown in FIG. 4, the first planarization portion 21 extends from the non-display region A2 to the bridge region B and is connected with the first planarization layer 20 located in the bridge region B. During specific implementation, the first planarization portion 21 extends from the non-display region A2 to the bridge region B. In this way, during actual manufacturing, the first planarization portion 21 is made to extend from the non-display region A2 to the bridge region B during patterning of the first planarization layer 20. Thus, a manufacturing process of the first recess 22 is simplified, and the manufacturing efficiency of the display substrate is improved. In addition, the first planarization portion 21 is connected with the first planarization layer 20 located in the bridge region B. In this way, while the manufacturing process of the first recess 22 is simplified, structural stability of subsequent film layers of the first planarization portion 21 is guaranteed, and usability of the display substrate is improved.

With reference to the illustrative embodiment as shown in FIG. 4, the second planarization portion 41 is separated from the second planarization layers 40 located in both the display region A1 and the bridge region B. In this way, the encapsulation effect of the display substrate at the connection position of the island and the bridge is improved.

With reference to the illustrative embodiment as shown in FIG. 5, the second planarization portion 41 is connected with the second planarization layer 40 located in the display region A1 and separated from the second planarization layer 40 located in the bridge region B. In this way, deflation of the second planarization layer 40 located in the display region A1 is facilitated during manufacturing, film explosion of the second planarization layer 40 in the display region A1 is avoided, and the manufacturing efficiency of the display substrate is improved. It should be noted that during actual manufacturing, a radius of an opening of the concave structure 60 in the illustrative embodiment as shown in FIG. 5 is smaller than a radius of an opening of the concave structure 60 in the illustrative embodiment as shown in FIG. 4. Thus, the second planarization portion 41 is guaranteed to be connected with the second planarization layer 40 located in the display region A1.

It should be noted that in the illustrative embodiments shown in FIGS. 4 and 5, the first recess 22 is arranged at an end, close to the display region A1, of the concave structure 60, and the orthographic projection of the first recess 22 on the flexible substrate 10 partially overlaps an orthographic projection of the concave structure 60 on the flexible substrate 10.

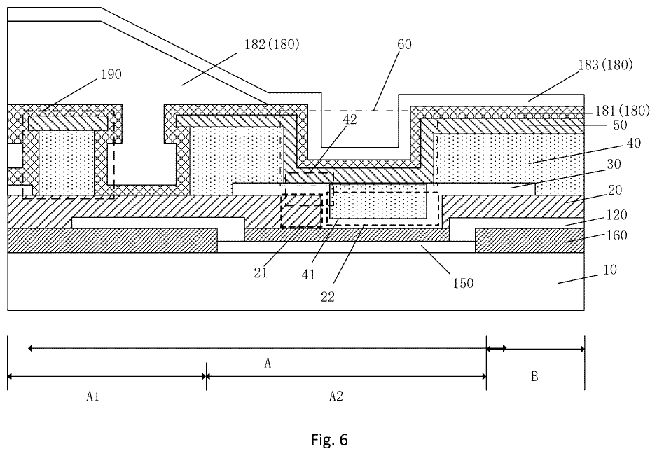

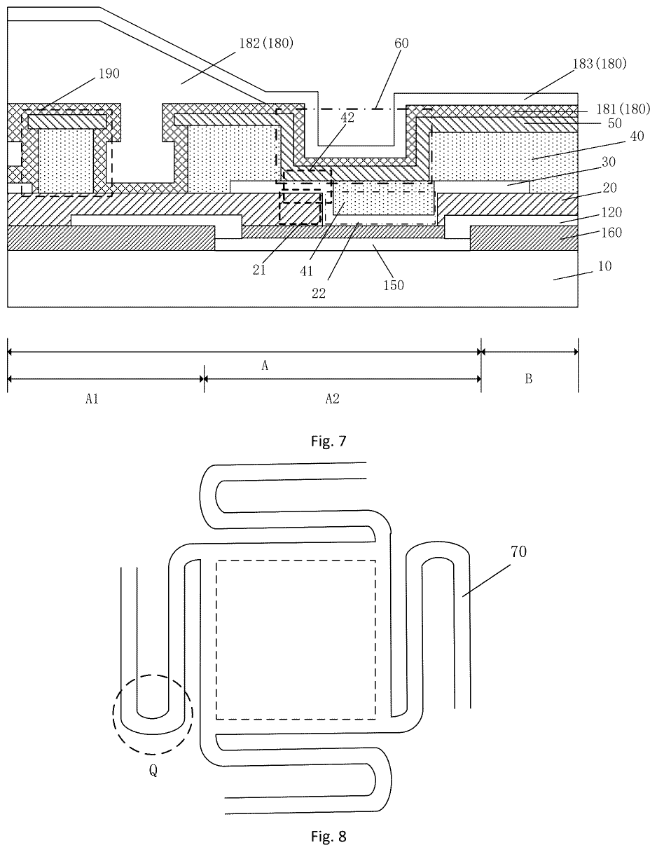

In an illustrative embodiment, as shown in FIGS. 6 and 7, one first recess 22 is provided, one second recess 42 is provided, and the second recess 42 is provided at a side close to the display region A1.

During specific implementation, as shown in FIGS. 6 and 7, one first recess 22 is provided and one second recess 42 is provided. In addition, an area of the orthographic projection of the second recess 42 on the flexible substrate 10 is smaller than an area of the orthographic projection of the first recess 22 on the flexible substrate 10. In this way, a manufacturing process of the second planarization portion 41 between the concave structure 60 and the flexible substrate 10 is simpler, the manufacturing efficiency of the display substrate is improved, and diversified design of the display substrate is achieved.

With reference to the illustrative embodiment as shown in FIG. 6, the first planarization portion 21 extends from the non-display region A2 to the display region A1 and is connected with the first planarization layer 20 located in the display region. In this way, during actual manufacturing, the first planarization portion 21 is made to extend from the non-display region A2 to the display region A1 during patterning of the first planarization layer 20. Thus, a manufacturing process of the first recess 22 is simplified, and the manufacturing efficiency of the display substrate is improved. In addition, the first planarization portion 21 is connected with the first planarization layer 20 located in the display region A1. In this way, while the manufacturing process of the first recess 22 is simplified, structural stability of subsequent film layers of the first planarization layer 20 of this part is guaranteed, and usability of the display substrate is improved.

With reference to the illustrative embodiment as shown in FIG. 6, the second planarization portion 41 is separated from the second planarization layers 40 located in both the display region A1 and the bridge region B. In this way, the encapsulation effect of the display substrate at the connection position of the island and the bridge is improved.

With reference to the illustrative embodiment as shown in FIG. 7, the second planarization portion 41 is connected with the second planarization layer 40 located in the bridge region B and separated from the second planarization layer 40 located in the display region A1. In this way, deflation of the second planarization layer 40 located in the bridge region B is facilitated during manufacturing, film explosion of the second planarization layer 40 in the bridge region B is avoided, and the manufacturing efficiency of the display substrate is improved. It should be noted that during actual manufacturing, a radius of an opening of the concave structure 60 in the illustrative embodiment as shown in FIG. 7 is smaller than a radius of an opening of the concave structure 60 in the illustrative embodiment as shown in FIG. 6. Thus, the second planarization portion 41 is guaranteed to be connected with the second planarization layer 40 located in the bridge region B.

It should be noted that a distance between a portion, adjacent to the concave structure 60 and close to a side of the display region A1, of the second planarization layer 40 and a portion, adjacent to the concave structure 60 and close to a side of the bridge region B, of the second planarization layer 40 in a direction from the island region A to the bridge region B is equal to a diameter of an opening of the concave structure 60. The diameter of the opening is twice a radius of the opening. In the illustrative embodiment as shown in FIG. 3, a numerical range of the diameter of the opening is greater than or equal to 6 μm. In the illustrative embodiment as shown in FIG. 4, a numerical range of the diameter of the opening is greater than or equal to 4 μm. Of course, the diameter of the opening of the concave structure 60 can be set according to actual application demands, and is not limited herein.

In addition, in the illustrative embodiments shown in FIGS. 6 and 7, the first recess 22 is arranged at an end, close to the bridge region B, of the concave structure 60, and the orthographic projection of the first recess 22 on the flexible substrate 10 partially overlaps an orthographic projection of the concave structure 60 on the flexible substrate 10.

In the embodiment of the disclosure, the first passivation layer 30 located between the concave structure 60 and the flexible substrate 10 extends from the non-display region A2 to the bridge region B, and is separated from the first passivation layer located in the display region A1. At the concave structure 60, an extension length of the first passivation layer 30 is smaller than an extension length of the second passivation layer 50 in the direction from the island region A to the bridge region B. A first source-drain electrode layer 120 located between the concave structure 60 and the flexible substrate 10 is separated from the first source-drain electrode layer located in the display region A1. In addition, the orthographic projection of the second recess 22 on the flexible substrate 10 completely falls within a region of the orthographic projection of the concave structure 60 on the flexible substrate 10. The orthographic projection of the concave structure 60 on the flexible substrate 10 completely falls within a region of an orthographic projection of a first gate layer 150 on the flexible substrate 10.

In the embodiment of the disclosure, the bridge region B is a bendable bridge 70 or an I-shaped bridge.

In an illustrative embodiment, the bridge region B may be the bendable bridge 70. As shown in FIG. 8, a schematic structural diagram of a top view of a display substrate with a bridge region B being a bendable bridge 70 is shown. A dotted box Q in FIG. 8 indicates a corner position of the bendable bridge 70.

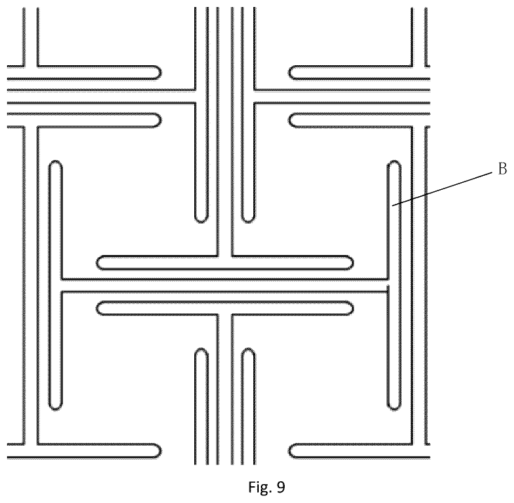

In an illustrative embodiment, the bridge region B may be the I-shaped bridge. As shown in FIG. 9, a schematic structural diagram of a top view of a display substrate with a bridge region B being an I-shaped bridge is shown.

During the actual research, the inventor found that when the bendable bridge 70 is used to design screen stretching and dome deformation, a failure position often occurs at the corner position of the bendable bridge 70. Once the resistance to fracture failure of the bendable bridge 70 at the corner position is improved, deformability of a display screen can be greatly improved.

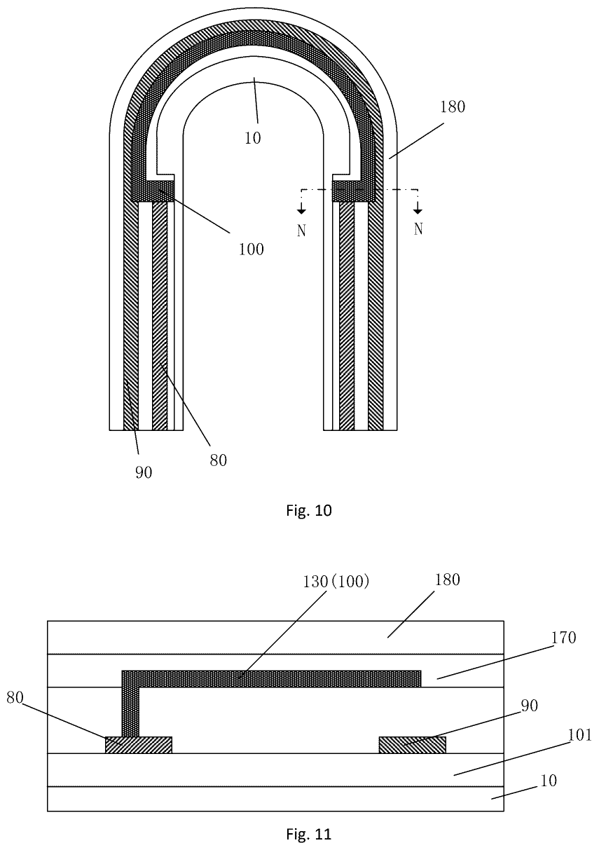

In the embodiments of the disclosure, as shown in FIGS. 10 and 11, FIG. 10 is a schematic structural diagram of a top view at a corner position of a bendable bridge 70, and FIG. 11 is a schematic structural diagram of a section in a direction indicated by NN in FIG. 10. Specifically, the bridge region B is the bendable bridge 70, and the bendable bridge 70 includes a first signal wire 80 and a second signal wire 90 that are arranged side by side on the flexible substrate 10. At a non-corner position of the bendable bridge 70, the first signal wire 80 is arranged closer to an inner side of a corner of the bendable bridge 70 than the second signal wire 90. At the corner of the bendable bridge 70, the first signal wire 80 and a metal wire 100 that is close to an outer side of the corner are lap-jointed.

During specific implementation, the bridge region B is the bendable bridge 70, and the bendable bridge 70 includes the first signal wire 80 and the second signal wire 90 that are arranged side by side on the flexible substrate 10. One or more first signal wires 80 may be provided. One or more second signal wires 90 may be provided. In an illustrative embodiment as shown in FIG. 10, one first signal wire 80 and one second signal wire 90 are provided. Of course, in an actual application, the number of the first signal wires 80 and the number of the second signal wires 90 can be set according to actual application demands, and are not limited herein. At the non-corner position of the bendable bridge 70, the first signal wire 80 is arranged closer to an inner side of a corner of the bendable bridge 70 than the second signal wire 90. At the corner of the bendable bridge 70, the first signal wire 80 and the metal wire 100 that is close to the outer side of the corner are lap-jointed. That is, at the corner of the bendable bridge 70, the metal wire 100 that is close to the outer side of the corner replaces a wire close to the inner side of the corner by lapping. In this way, the metal wire 100 that is close to the outer side of the corner is merely subjected to compressive stress during stretching, thus improving stretchability of the display substrate.

It should be noted that when a plurality of first signal wires 80 are provided, at the corner of the bendable bridge 70, at least a part of the plurality of first signal wires 80 may be lap-jointed to the metal wire 100 that is close to the outer side of the corner. For example, four signal wires are provided at a corner of an original display substrate. In the specific embodiment of the disclosure, two signal wires close to the inner side of the corner may be lap-jointed to the metal wire that is close to the outer side. In an illustrative embodiment, one signal wire close to the inner side of the corner is lap-jointed to an anode layer 130, and the other signal wire close to the inner side of the corner is lap-jointed to the source-drain electrode layer. Of course, a lap-jointed mode of relevant signal wires at the corner can be further designed according to actual application demands, and is not elaborated herein.

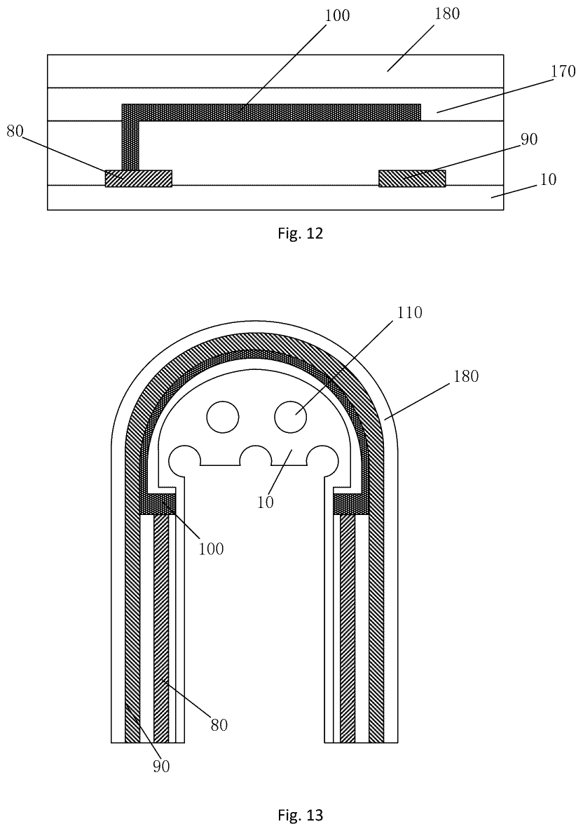

In the embodiment of the disclosure, FIG. 12 shows another schematic structural diagram of a section in the direction indicated by NN in FIG. 10. Specifically, at the corner of the bendable bridge 70, the first signal wire 80 is in direct contact with the flexible substrate 10.

During actual manufacturing, at least one inorganic insulation layer 101 at the inner side of the corner of the bendable bridge 70 may be etched away. The at least one inorganic insulation layer 101 may be at least one of a first gate insulation layer, a second gate insulation layer, an interlayer insulation layer 160, the first passivation layer 30 or the second passivation layer 50. In an illustrative embodiment, merely the flexible substrate 10 is kept at the inner side of the corner, and the first signal wire 80 is in direct contact with the flexible substrate 10 at the corner of the bendable bridge 70 accordingly. Thus, a risk of fracture caused by the inorganic insulation layer at the corner of the bendable bridge 70 is reduced, and the usability of the display substrate is improved.

In the embodiment of the disclosure, at the corner of the bendable bridge 70, at least one hole 110 penetrating in a thickness direction of the flexible substrate is provided at a position on the flexible substrate 10 excluding positions where the first signal wire 80 and the second signal wire 90 are arranged.

In an illustrative embodiment, FIG. 13 is another schematic structural diagram of a top view of the corner position of the bendable bridge 70 in FIG. 8. Specifically, at the corner of the bendable bridge 70, at least one hole 110 penetrating in a thickness direction of the flexible substrate is provided at a position on the flexible substrate 10 excluding positions where the first signal wire 80 and the second signal wire 90 are arranged. One or more holes 110 may be provided, which is not limited herein. When a plurality of holes 110 are provided, the plurality of holes can be uniformly distributed with an equal density or nonuniformly distributed, which is not limited herein. During actual manufacturing, diameters of the holes may be the same or different, and may be set according to actual application demands, which is not limited herein. In this way, a stretching amount of the display substrate is improved. It should be noted that during actual manufacturing, a thick flexible substrate 10 may be kept at the corner of the bendable bridge 70, thus improving the hole opening efficiency of the at least one hole 110.

In the embodiment of the disclosure, the display substrate further includes a first source-drain electrode layer 120 arranged on the flexible substrate 10, and the first source-drain electrode layer 120 is manufactured on the same layer as the first signal wire 80. That is, during actual manufacturing, the first source-drain electrode layer 120 and the first signal wire 80 may be manufactured on the same layer, thus simplifying the manufacturing process.

In the embodiment of the disclosure, the display substrate further includes an anode layer 130 at a side, facing away from the flexible substrate 10, of the first source-drain electrode layer 120; and the anode layer 130 is manufactured on the same layer as the metal wire 100. In the illustrative embodiment as shown in FIG. 11, the metal wire 100 that is close to the outer side of the corner is manufactured on the same layer as the anode layer 130.

Correspondingly, a film layer between a thin film encapsulation layer 180 and the metal wire 100 may be a pixel defining layer 170. The film layers between the metal wire 100 and the signal wire may be, for example, the first planarization layer 20 and the second planarization layer 40. A film layer between the flexible substrate 10 and the signal wire may be at least one inorganic insulation layer 101. In this way, during actual manufacturing, the metal layer corresponding to the anode layer may be used to manufacture the metal wire 100 that is close to the outer side of the corner, thus simplifying the manufacturing process and improving the manufacturing efficiency of the display substrate.

In the embodiment of the disclosure, the display substrate further includes a second source-drain electrode layer 140 between the first source-drain electrode layer 120 and the flexible substrate 10, and the second source-drain electrode layer 140 is manufactured on the same layer as the metal wire 100.

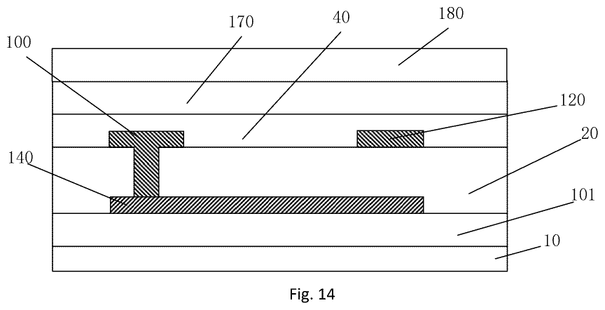

During specific implementation, as shown in FIG. 14, another schematic structural diagram of a section in the direction indicated by NN in FIG. 10 is shown. Specifically, the display substrate further includes the second source-drain electrode layer 140 between the first source-drain electrode layer 120 and the flexible substrate 10. The second source-drain electrode layer 140 may be manufactured on the same layer as the metal wire 100 that is close to the outer side of the corner. In this way, during actual manufacturing, the metal layer corresponding to the second source-drain electrode layer 140 may be used to manufacture the metal wire 100 that is close to the outer side of the corner, thus simplifying the manufacturing process and improving the manufacturing efficiency of the display substrate.

It should be noted that the bendable bridge 70 of the display substrate further includes other film layers, such as an active layer, the first gate insulation layer, a first gate layer 150, the second gate insulation layer, a second gate layer, the interlayer insulation layer 160 and the first source-drain electrode layer 120 that are sequentially arranged on the flexible substrate 10 besides the film layers described above. The first planarization layer 20, the first passivation layer 30, the second planarization layer 40 and the second passivation layer 50 are arranged sequentially at a side, facing away from the flexible substrate 10, of the first source-drain electrode layer 120. The anode layer, the pixel defining layer 170, a light emitting layer, a cathode layer, and a thin film encapsulation layer (TFE) 180 are further arranged sequentially at a side, facing away from the flexible substrate 10, of the second passivation layer 50. In the foregoing illustrative embodiment, the thin film encapsulation layer 180 includes a first inorganic encapsulation layer 181, an organic encapsulation layer 182 and a second inorganic encapsulation layer 183, thus ensuring encapsulation performance of the display substrate. Specific arrangements of these film layer structures can be implemented with reference to the related art, and are not elaborated herein. Of course, in an actual application, besides the film layer structures mentioned, the display substrate can further include other film layer structures, which is not be elaborated herein.

Based on the same concept disclosed, the embodiments of the disclosure further provide a display device. The display device includes the display substrate described above. The display substrate may be an organic light emitting diode (OLED) display substrate. The display substrate may be a stretchable display substrate, and correspondingly, the display device may be a stretchable display device. Since a principle of solving problems by the display device is similar to that of the foregoing display substrate, reference can be made to implementation of the display substrate for implementation of the display device, and any repeated content will not be repeated herein.

During specific implementation, the display device according to the embodiments of the disclosure may be any product or component that has a display function, such as a mobile phone, a tablet computer, a television, a display, a notebook computer, a digital photo frame and a navigator. Other essential components of the display device should be understood as necessary by those of ordinary skill in the art, are not repeated herein, and should not be regarded as limitation to the disclosure.

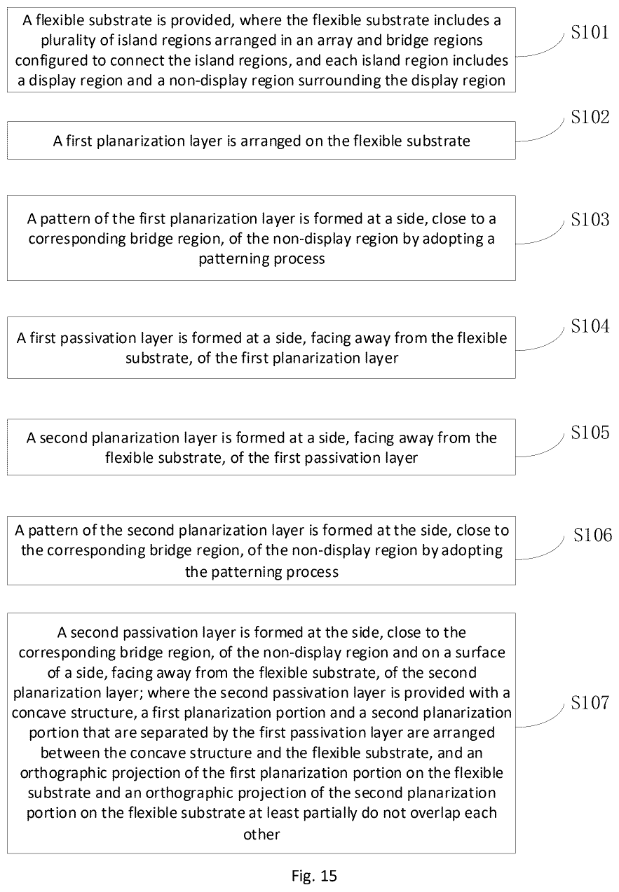

Based on the same concept disclosed, the embodiments of the disclosure further provide a manufacturing method for a display substrate as shown in FIG. 15. The manufacturing method is configured to manufacture the display substrate above, and the manufacturing method includes the following.

S101: A flexible substrate is provided, where the flexible substrate includes a plurality of island regions arranged in an array and bridge regions configured to connect the island regions, and each island region includes a display region and a non-display region surrounding the display region.

S102: A first planarization layer is arranged on the flexible substrate.

S103: A pattern of the first planarization layer is formed at a side, close to a corresponding bridge region, of the non-display region by adopting a patterning process.

S104: A first passivation layer is formed at a side, facing away from the flexible substrate, of the first planarization layer.

S105: A second planarization layer is formed at a side, facing away from the flexible substrate, of the first passivation layer.

S106: A pattern of the second planarization layer is formed at the side, close to the corresponding bridge region, of the non-display region by adopting the patterning process.

S107: A second passivation layer is formed at the side, close to the corresponding bridge region, of the non-display region and on a surface of a side, facing away from the flexible substrate, of the second planarization layer; where the second passivation layer is provided with a concave structure, a first planarization portion and a second planarization portion that are separated by the first passivation layer are arranged between the concave structure and the flexible substrate, and an orthographic projection of the first planarization portion on the flexible substrate and an orthographic projection of the second planarization portion on the flexible substrate at least partially do not overlap each other. In some embodiments, the first planarization portion and the first planarization layer are located on the same layer and made of the same material, and the second planarization portion and the second planarization layer are located on the same layer and made of the same material.

During specific implementation, a specific implementation process from S101 to S107 is as follows.

Firstly, the flexible substrate is provided. The flexible substrate includes a plurality of island regions arranged in an array and bridge regions configured to connect the island regions, and each island region includes a display region and a non-display region surrounding the display region. Then, the first planarization layer is arranged on the flexible substrate. Before the first planarization layer is arranged, corresponding patterns of an active layer, a first gate insulation layer, a first gate layer, a second gate insulation layer, an interlayer insulation layer and a first source-drain electrode layer may be sequentially formed on the flexible substrate. Specific formation processes of corresponding patterns of the film layers may be implemented with reference to the related art, and are not elaborated herein.

Then, the pattern of the first planarization layer is formed at a side, close to a corresponding bridge region, of the non-display region by adopting the patterning process. In the illustrative embodiment as shown in FIG. 2, the first planarization layer keeps a part of the pattern in a middle region of a corresponding position of the concave structure, and thus the first planarization portion between the concave structure and the flexible substrate is provided with a first sub-recess and a second sub-recess. In the illustrative embodiment as shown in FIG. 4, the part of the pattern of the first planarization layer kept at a corresponding position of the concave structure is arranged close to the bridge region, and the first planarization layer is provided with one first recess between the concave structure and the flexible substrate. Of course, the pattern of the first planarization layer can also be set according to actual application demands, which is not elaborated herein.

The pattern of the first passivation layer is formed at the side, facing away from the flexible substrate, of the first planarization layer after the pattern of the first planarization layer is formed. Then, the second planarization layer is formed at the side, facing away from the flexible substrate, of the first passivation layer. Then, the pattern of the second planarization layer is formed at the side, close to the corresponding bridge region, of the non-display region by adopting the patterning process. In the illustrative embodiment as shown in FIG. 2, the second planarization layer keeps a partial pattern between the concave structure and the flexible substrate, and a second planarization portion at a corresponding position is provided with a second recess corresponding to the first planarization portion. The second planarization portion includes a first sub-portion located at a side, close to the display region, of the second recess and a second sub-portion located at a side, close to the bridge region, of the second recess. Of course, the pattern of the second planarization layer can further be set according to actual application demands, which is not elaborated herein.

It should be noted that in the embodiments of the disclosure, the “patterning process” mainly uses exposure, development and etching to form a pattern of a corresponding film layer.

After the pattern of the second planarization layer is formed, the second passivation layer is formed at the side, close to the corresponding bridge region, of the non-display region and on a surface of the side, facing away from the flexible substrate, of the second planarization layer. Then, the pattern of the second passivation layer is formed, and the second passivation layer is provided with the concave structure. In addition, a post spacer may be formed at a side of the non-display region close to the display region through a reserved second passivation layer and a reserved second planarization layer. An isolation effect of water and oxygen at a connection position of the island and the bridge is further improved. In addition, a surface of a side, close to the flexible substrate, of the concave structure is conformally arranged on surfaces, far away from the flexible substrate, of the first passivation layer and the second planarization portion, thus ensuring structural stability of a subsequent film layer arrangement and improving usability of the display substrate. In addition, the first planarization portion and a second planarization portion that are separated by the first passivation layer are arranged between the concave structure and the flexible substrate, and the orthographic projection of the first planarization portion on the flexible substrate and the orthographic projection of the second planarization portion on the flexible substrate at least partially do not overlap each other.

It should be noted that during actual manufacturing, after the pattern of the second planarization layer is formed, a thin film encapsulation layer is formed on a surface of the side, facing away from the flexible substrate, of the second passivation layer. The thin film encapsulation layer includes inorganic layers and an organic layer that are overlapped. During specific implementation, despite a type of structure of the thin film encapsulation layer, a top layer of the thin film encapsulation layer is set as the inorganic layer for effectively blocking water and oxygen, thus improving usability of the display substrate. The material of the inorganic layer may be at least one of silicon oxide, silicon nitride and silicon oxynitride, and the material of the organic layer may be an organic material suitable for inkjet printing.

The embodiments of the disclosure provide the display substrate, the manufacturing method therefor and the display device. The display substrate includes: the flexible substrate; and the first planarization layer, the first passivation layer, the second planarization layer and the second passivation layer that are sequentially arranged on the flexible substrate. The flexible substrate includes the plurality of island regions arranged in an array and the bridge region configured to connect the island regions. Each island region includes the display region and the non-display region surrounding the display region. The second passivation layer is provided with the concave structure at the side, close to the corresponding bridge region, of the non-display region; and the surface of the side, close to the flexible substrate, of the concave structure is conformally arranged on the surfaces, far away from the flexible substrate, of the first passivation layer and the second planarization portion. Thus, flatness of subsequent film layers is guaranteed. The first planarization portion and the second planarization portion that are separated by the first passivation layer are arranged between the concave structure and the flexible substrate, and the orthographic projection of the first planarization portion on the flexible substrate and the orthographic projection of the second planarization portion on the flexible substrate at least partially do not overlap each other. That is, the pattern of the first planarization portion and the pattern of the second planarization layer are reserved between the concave structure and the flexible substrate. In this way, the first planarization portion and the second planarization portion located between the concave structure and the flexible substrate raise the concave structure, thus avoiding the risk of adhesive residue during exposure in deep holes in a subsequent process.

Although the preferred embodiments of the disclosure have been described, additional alterations and modifications can be made to those embodiments by a person of ordinary skill once the basic inventive concepts are learned. Thus, the appended claims are intended to be constructed to include the preferred embodiments and all alterations and modifications that fall within the scope of the disclosure.

Apparently, those skilled in the art can make various modifications and variations to the disclosure without departing from the spirit and scope of the disclosure. In this way, if these modifications and variations of the disclosure fall within the scope of the claims of the disclosure and their equivalent technologies, the disclosure is also intended to include these modifications and variations.

1-25. (canceled)

26. A display substrate, comprising:
a flexible substrate; and
a first planarization layer, a first passivation layer, a second planarization layer and a second passivation layer that are sequentially arranged on the flexible substrate; wherein the flexible substrate comprises a plurality of island regions arranged in an array and bridge regions configured to connect the plurality of island regions;
wherein each of the plurality of island regions comprises a display region and a non-display region surrounding the display region;
the second passivation layer is provided with a concave structure at a side, close to a corresponding bridge region, of the non-display region; and
a first planarization portion and a second planarization portion that are separated by the first passivation layer are arranged between the concave structure and the flexible substrate, and an orthographic projection of the first planarization portion on the flexible substrate and an orthographic projection of the second planarization portion on the flexible substrate at least partially do not overlap each other.

27. The display substrate of claim 26, wherein the first planarization portion and the first planarization layer are located on a same layer and made of a same material, and the second planarization portion and the second planarization layer are located on a same layer and made of a same material; and
the first planarization portion is provided with at least one first recess and the second planarization portion is provided with at least one second recess between the concave structure and the flexible substrate, and an orthographic projection of the at least one second recess on the flexible substrate and an orthographic projection of the at least one first recess on the flexible substrate do not overlap each other.

28. The display substrate of claim 27, wherein between the concave structure and the flexible substrate, a partial surface of a side, facing away from the flexible substrate, of the first passivation layer is flush with a surface of a side, facing away from the flexible substrate, of the second planarization portion; and
the second passivation layer is in direct contact with the first passivation layer at a position corresponding to the first planarization portion.

29. The display substrate of claim 28, wherein the at least one first recess comprises a first sub-recess and a second sub-recess that are separated by the first planarization portion; and
the first sub-recess is close to the display region, and the second sub-recess is close to the bridge region;
wherein one second recess is provided;
wherein the second planarization portion comprises:
a first sub-portion at a side, close to the display region, of the second recess; and
a second sub-portion at a side, close to the bridge region, of the second recess.

30. The display substrate of claim 29, wherein the first sub-portion is separated from the second planarization layer in the display region; and
the second sub-portion is separated from the second planarization layer in the bridge region.

31. The display substrate of claim 29, wherein the first sub-portion is connected with the second planarization layer in the display region, and the second sub-portion is connected with the second planarization layer in the bridge region.

32. The display substrate of claim 28, wherein one first recess is provided, one second recess is provided, and the second recess is at a side close to the bridge region.

33. The display substrate of claim 32, wherein the first planarization portion extends from the non-display region to the bridge region and is connected with the first planarization layer in the bridge region.

34. The display substrate of claim 33, wherein the second planarization portion is separated from the second planarization layer in both the display region and the bridge region.

35. The display substrate of claim 33, wherein the second planarization portion is connected with the second planarization layer in the display region and is separated from the second planarization layer in the bridge region.

36. The display substrate of claim 28, wherein one first recess is provided, one second recess is provided, and the second recess is at a side close to the display region.

37. The display substrate of claim 36, wherein the first planarization portion extends from the non-display region to the display region and is connected with the first planarization layer in the display region.

38. The display substrate of claim 37, wherein the second planarization portion is separated from the second planarization layer in both the display region and the bridge region.

39. The display substrate of claim 37, wherein the second planarization portion is connected with the second planarization layer in the bridge region and is separated from the second planarization layer in the display region.

40. The display substrate of claim 26, wherein the bridge region is a bendable bridge or an I-shaped bridge.

41. The display substrate of claim 40, wherein the bridge region is the bendable bridge, and the bendable bridge comprises a first signal wire and a second signal wire that are arranged side by side on the flexible substrate;
at a non-corner position of the bendable bridge, the first signal wire is closer to an inner side of a corner of the bendable bridge than the second signal wire; and
at the corner of the bendable bridge, the first signal wire and a metal wire that is close to an outer side of the corner are lap-jointed;
wherein at the corner of the bendable bridge, the first signal wire is in direct contact with the flexible substrate.

42. The display substrate of claim 40, wherein at the corner of the bendable bridge, at least one hole penetrating in a thickness direction of the flexible substrate is provided at a position on the flexible substrate excluding positions where the first signal wire and the second signal wire are arranged.

43. The display substrate of claim 41, further comprising a first source-drain electrode layer on the flexible substrate, wherein the first source-drain electrode layer is manufactured on a same layer as the first signal wire;
wherein the display substrate further comprises:
an anode layer at a side, facing away from the flexible substrate, of the first source-drain electrode layer, wherein the anode layer is manufactured on a same layer as the metal wire; and/or,
a second source-drain electrode layer between the first source-drain electrode layer and the flexible substrate, wherein the second source-drain electrode layer is manufactured on a same layer as the metal wire.

44. The display substrate of claim 26, further comprising a thin film encapsulation layer;
wherein the thin film encapsulation layer comprises a first inorganic encapsulation layer, an organic encapsulation layer and a second inorganic encapsulation layer;
the organic encapsulation layer is at a side, close to the display region, of the concave structure; and
in the non-display region and the bridge region, the first inorganic encapsulation layer and the second inorganic encapsulation layer are in direct contact with each other and cover the concave structure.

45. A display device, comprising: the display substrate of claim 26.
